(19) United States
(12) Patent Application Publication
(10) Pub. No.: US 2025/0294834 A1
(43) Pub. Date: Sep. 18, 2025

(54) SEMICONDUCTOR DEVICE AND METHOD OF MANUFACTURING SEMICONDUCTOR DEVICE

(71) Applicant: INSTITUTE OF MICROELECTRONICS, CHINESE ACADEMY OF SCIENCES, Beijing (CN)

(72) Inventors: Huilong ZHU, Poughkeepsie, NY (US); Xianyu CHEN, Beijing (CN); Yongkui ZHANG, Beijing (CN); Jun LUO, Beijing (CN); Tianchun YE, Beijing (CN); Wenliang LIU, Beijing (CN)

(73) Assignee: INSTITUTE OF MICROELECTRONICS, CHINESE ACADEMY OF SCIENCES, Beijing (CN)

(21) Appl. No.: 18/754,316

(22) Filed: Jun. 26, 2024

(30) Foreign Application Priority Data
Mar. 15, 2024 (CN) 202410302737.2

(51) Int. Cl. H01L 29/10; H01L 21/225; H01L 29/66; H01L 29/78

(52) U.S. Cl. CPC H10D 62/307; H01L 21/225; H10D 30/025; H10D 30/63

(57) ABSTRACT

The present disclosure provides a semiconductor device and a method of manufacturing a semiconductor device, which may be applied to the field of semiconductor technology. The semiconductor device includes: a first source/drain layer, a channel layer and a second source/drain layer sequentially provided in a vertical direction on a substrate, where the channel layer is connected between the first source/drain layer and the second source/drain layer, and the channel layer has a doping profile along the vertical direction, in which a middle portion of the channel layer has a high doping concentration and end portions of the channel layer have a low doping concentration; and a body contact connected to the middle portion of the channel layer, where the middle portion of the channel layer has a height in the vertical direction greater than a height of the body contact in the vertical direction.

### CROSS REFERENCE TO RELATED APPLICATION

This application claims priority to Chinese Patent Application No. 202410302737.2, filed on Mar. 15, 2024, the entire content of which is incorporated herein in its entirety by reference.

### TECHNICAL FIELD

The present disclosure relates to the field of semiconductor technology, and in particular to a semiconductor device and a method of manufacturing a semiconductor device.

### BACKGROUND

In order to meet requirements of increasing miniaturization of semiconductor devices, various device structures have been proposed, such as fin field-effect transistor (FinFET), multi-bridge-channel field-effect transistor (MBCFET), saddle-fin field-effect transistor (Saddle-Fin FET), and so on. However, these device structures still have some limitations.

Vertical FET is an MOSFET that has a promising prospect in terms of miniaturization. In order to further reduce a size of a DRAM memory cell, a body-contacted vertical channel transistor (BCVCT) is used as an access transistor. However, gate induced drain leakage (GIDL) and floating body effect (FBE) of BCVCT may induce negative drift of threshold voltage and an increase in off-state current of conventional BCVCT.

### SUMMARY

The present disclosure provides a semiconductor device and a method of manufacturing a semiconductor device.

In a first aspect of the present disclosure, a semiconductor device is provided, including: a first source/drain layer, a channel layer and a second source/drain layer sequentially provided in a vertical direction on a substrate, where the channel layer is connected between the first source/drain layer and the second source/drain layer, and the channel layer has a doping profile along the vertical direction, in which a middle portion of the channel layer has a high doping concentration and end portions of the channel layer have a low doping concentration; and a body contact connected to the middle portion of the channel layer, where the middle portion of the channel layer has a height in the vertical direction greater than a height of the body contact in the vertical direction.

According to the embodiments of the present disclosure, the middle portion of the channel layer has a substantially uniform doping profile.

According to the embodiments of the present disclosure, the middle portion of the channel layer is substantially symmetrical with respect to the body contact; or the middle portion of the channel layer is asymmetrical with respect to the body contact.

According to the embodiments of the present disclosure, an extension height of the middle portion of the channel layer relative to a top surface of the body contact in the vertical direction is substantially equal to an extension height of the middle portion of the channel layer relative to a bottom surface of the body contact in the vertical direction; or an extension height of the middle portion of the channel layer relative to a top surface of the body contact in the vertical direction is greater than an extension height of the middle portion of the channel layer relative to a bottom surface of the body contact in the vertical direction; or an extension height of the middle portion of the channel layer relative to a top surface of the body contact in the vertical direction is less than an extension height of the middle portion of the channel layer relative to a bottom surface of the body contact in the vertical direction.

According to the embodiments of the present disclosure, a doping type in the channel layer is opposite to a doping type in the first source/drain layer and in the second source/drain layer.

According to the embodiments of the present disclosure, the channel layer extends vertically.

According to the embodiments of the present disclosure, the body contact extends laterally.

In a second aspect of the present disclosure, a method of manufacturing a semiconductor device is provided, including: providing a stack of a first source/drain defining layer, a first channel defining layer, a body contact defining layer, a second channel defining layer and a second source/drain defining layer on a substrate, where the body contact defining layer contains a dopant; forming a channel layer on a vertical sidewall of the stack; and driving the dopant in the body contact defining layer into the channel layer to form a doping profile in the channel layer, so that a doping concentration in a first portion of the channel layer connected to the body contact defining layer is greater than a doping concentration in a second portion of the channel layer adjacent to the first portion.

According to the embodiments of the present disclosure, the method further includes: forming a first auxiliary layer between the first source/drain defining layer and the first channel defining layer; and forming a second auxiliary layer between the second channel defining layer and the second source/drain defining layer, where, in a process of driving the dopant in the body contact defining layer into the channel layer, a dopant in the first source/drain defining layer is driven into a portion of the channel layer on a sidewall of the first auxiliary layer, and a dopant in the second source/drain defining layer is driven into a portion of the channel layer on a sidewall of the second auxiliary layer, so that a partial region in a portion of the channel layer on a sidewall of the first channel defining layer and in a portion of the channel layer on a sidewall of the second channel defining layer remains lightly doped relative to the first portion.

According to the embodiments of the present disclosure, the method further includes: forming a third auxiliary layer between the first channel defining layer and the body contact defining layer; and forming a fourth auxiliary layer between the body contact defining layer and the second channel defining layer; where, in the process of driving the dopant in the body contact defining layer into the channel layer, a dopant in the third auxiliary layer is driven into the portion of the channel layer on the sidewall of the first channel defining layer, a dopant in the fourth auxiliary layer is driven into the portion of the channel layer on the sidewall of the second channel defining layer, and the dopant in the body contact defining layer is driven into a portion of the channel layer on a sidewall of the body contact defining layer, so that a partial region of the channel layer on the sidewall of the body contact defining layer, on a sidewall of the third auxiliary layer, on a sidewall of the fourth auxiliary layer, on an upper part of the sidewall of the first channel defining layer and on a lower part of the sidewall of the second channel defining layer remains highly doped relative to the second portion.

### BRIEF DESCRIPTION OF THE DRAWINGS

The above and other objectives, features and advantages of the present disclosure will be more apparent through the following description of the embodiments of the present disclosure with reference to the accompanying drawings. In the accompanying drawings:

FIG. 1 to FIG. 13 schematically show some stages in a process of manufacturing a semiconductor device according to the embodiments of the present disclosure.

Throughout the accompanying drawings, the same or similar reference numbers may denote the same or similar components. The accompanying drawings are not necessarily drawn to scale. Especially, for clarity, cross-sectional views are drawn at different scales from top views.

### DETAILED DESCRIPTION OF EMBODIMENTS

Embodiments of the present disclosure will be described below with reference to the accompanying drawings. It should be understood, however, that these descriptions are just exemplary and are not intended to limit the scope of the present disclosure. In the following detailed descriptions, for the sake of explanation, many specific details are set forth to provide comprehensive understanding of the embodiments of the present disclosure. Obviously, however, one or more embodiments may also be implemented without these specific details. In addition, in the following, descriptions of well-known structures and technologies are omitted to avoid unnecessarily obscuring the concepts of the present disclosure.

Various schematic structural diagrams according to the embodiments of the present disclosure are shown in the accompanying drawings. These drawings are not drawn to scale. Some details are enlarged and some details may be omitted for clarity of presentation. The shapes of the various regions and layers as well as the relative size and positional relationship thereof shown in the drawings are just exemplary. In practice, there may be deviations due to manufacturing tolerances or technical limitations, and those skilled in the art may additionally design regions/layers with different shapes, sizes and relative positions according to actual needs.

In the context of the present disclosure, when a layer/element is referred to as being located “on” a further layer/element, the layer/element may be located directly on the further layer/element, or there may be an intermediate layer/element between them. In addition, if a layer/element is located “on” a further layer/element in one orientation, the layer/element may be located “under” the further layer/element when the orientation is reversed.

According to the embodiments of the present disclosure, a semiconductor device is provided, which may include: a first source/drain layer, a channel layer and a second source/drain layer arranged sequentially in a vertical direction on a substrate, as well as a body contact connected to a middle portion of the channel layer. The channel layer is connected between the first source/drain layer and the second source/drain layer.

The first source/drain layer and the second source/drain layer may be doped. For example, for a p-type device, the first source/drain layer and the second source/drain layer may be p-type doped; and for an n-type device, the first source/drain layer and the second source/drain layer may be n-type doped.

The channel layer may also be doped, and a doping type in the channel layer may be opposite to that in the first source/drain layer and the second source/drain layer. The channel layer may have a doping profile along the vertical direction, in which a middle portion of the channel layer has a high doping concentration and end portions of the channel layer have a low doping concentration. The highly-doped middle portion of the channel layer has a height in the vertical direction greater than a height of the body contact in the vertical direction.

The channel layer may contain a single crystal semiconductor material. The first source/drain layer and the second source/drain layer may also contain a single crystal semiconductor material. For example, they may all be formed by an epitaxial growth.

As the channel layer has a high doping concentration at the middle portion and a low doping concentration at the end portions and the end portions of the channel layer are close to the first source/drain layer and the second source/drain layer, the lightly-doped end portions of the channel layer may reduce an energy band barrier and an electric field intensity in a channel direction, thereby suppressing the band to band tunneling and reducing GIDL. In addition, the body contact is connected to the highly-doped middle portion of the channel layer, and the height of the middle portion in the vertical direction is greater than the height of the body contact in the vertical direction, but make sure that the middle portion does not affect a region where GIDL is generated, and there may be a clear depletion region, thereby achieving a control of an off-state current of the semiconductor device by a bias voltage of the body contact.

The highly-doped middle portion of the channel layer has substantially a uniform doping profile, which means that the doping profile is uniform in a range of not affecting a device performance.

The highly-doped middle portion of the channel layer may be substantially symmetrical with respect to the body contact.

The highly-doped middle portion of the channel layer may also be asymmetrical with respect to the body contact, which may be flexibly determined according to specific requirements for the device.

An extension height of the highly-doped middle portion of the channel layer relative to a top surface of the body contact in the vertical direction is substantially equal to an extension height of the highly-doped middle portion of the channel layer relative to a bottom surface of the body contact in the vertical direction.

The extension height of the highly-doped middle portion of the channel layer relative to the top surface of the body contact in the vertical direction may also be greater or less than the extension height of the highly-doped middle portion of the channel layer relative to the bottom surface of the body contact in the vertical direction, which may be flexibly determined according to specific requirements for the device.

The channel layer may extend vertically and have a thickness in a range of 10 nm to 20 nm. The body contact may extend laterally and have a thickness of 10 nm.

The semiconductor device may further include a gate electrode surrounding an outer periphery of the channel layer.

Such semiconductor device may be manufactured as follows.

A stack of a first source/drain defining layer, a first channel defining layer, a body contact defining layer, a second channel defining layer and a second source/drain defining layer is provided on a substrate. The stack may be formed by an epitaxial growth, so that a thickness of each layer therein may be well controlled. The layers in the stack may be doped in situ during growth in order to achieve desired doping characteristics. For example, the first source/drain defining layer and the second source/drain defining layer may be heavily doped to achieve source/drain regions, the body contact defining layer may be heavily doped, and the first channel defining layer and the second channel defining layer may not be doped.

After processes such as photolithography and etching, the stack may have a vertical sidewall extending in a first direction. A channel layer may be formed on such vertical sidewall. The channel layer may be formed by an epitaxial growth, and its thickness may therefore be well controlled. In addition, a material of the channel layer may be selected appropriately according to applications.

A dopant in the body contact defining layer may be driven into the channel layer by, for example, a heat treatment, to form a doping profile in the channel layer, so that a doping concentration in a first portion of the channel layer connected to the body contact defining layer is greater than a doping concentration in a second portion of the channel layer adjacent to the first portion.

A first auxiliary layer may be formed between the first source/drain defining layer and the first channel defining layer, and a second auxiliary layer may be formed between the second channel defining layer and the second source/drain defining layer. The first auxiliary layer and the second auxiliary layer may be lightly doped or unintentionally doped. Accordingly, in the process of driving the dopant in the body contact defining layer into the channel layer, a dopant in the first source/drain defining layer is driven into a portion of the channel layer on a sidewall of the first auxiliary layer, and a dopant in the second source/drain defining layer is driven into a portion of the channel layer on a sidewall of the second auxiliary layer, so that a partial region in a portion of the channel layer on a sidewall of the first channel defining layer and in a portion of the channel layer on a sidewall of the second channel defining layer may remain lightly doped relative to the first portion.

A third auxiliary layer may be formed between the first channel defining layer and the body contact defining layer, and a fourth auxiliary layer may be formed between the body contact defining layer and the second channel defining layer. The third auxiliary layer and the fourth auxiliary layer may be heavily doped. Accordingly, in the process of driving the dopant in the body contact defining layer into the channel layer, a dopant in the third auxiliary layer is driven into the portion of the channel layer on the sidewall of the first channel defining layer, a dopant in the fourth auxiliary layer is driven into the portion of the channel layer on the sidewall of the second channel defining layer, and the dopant in the body contact defining layer is driven into a portion of the channel layer on a sidewall of the body contact defining layer, so that a partial region of the channel layer on the sidewall of the body contact defining layer, on a sidewall of the third auxiliary layer, on a sidewall of the fourth auxiliary layer, on an upper part of the sidewall of the first channel defining layer and on a lower part of the sidewall of the second channel defining layer may remain highly doped relative to the second portion.

The present disclosure may be presented in various forms, some examples of which will be described below. A selection of various materials is involved in the following descriptions. In the selection of materials, in addition to functions of the materials (for example, a semiconductor material may be used to form an active region, a dielectric material may be used to form an electrical isolation, and a conductive material may be used to form an electrode, an interconnection structure, etc.), an etching selectivity is also considered. In the following descriptions, a required etching selectivity may or may not be indicated. It should be clear to those skilled in the art that when etching a material layer is mentioned below, if it is not mentioned or shown that other layers are also etched, then the etching may be selective, and the material layer may have an etching selectivity relative to other layers exposed to a same etching formula.

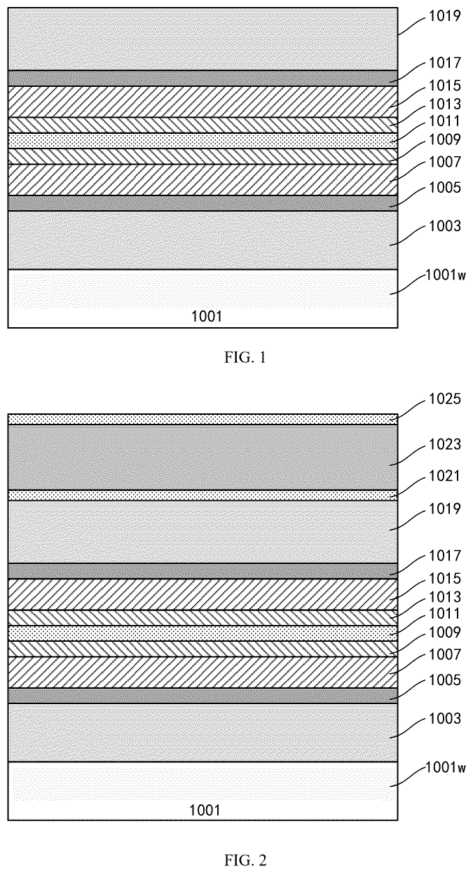

As shown in FIG. 1, a substrate 1001 is provided. The substrate 1001 may be in various forms, including but not limited to a bulk semiconductor material substrate such as a bulk Si substrate, a semiconductor-on-insulator (SOI) substrate, a compound semiconductor substrate such as a SiGe substrate, and the like. In the following descriptions, for the sake of explanation, a bulk Si substrate such as a Si wafer is taken as an example for description.

In the substrate 1001, a well region 1001w may be formed by, for example, an ion implantation. The well region 1001w may contain a dopant of a particular conduction type (e.g., a p-type conduction for an n-type device, or an n-type conduction for a p-type device) and a particular concentration such as in a range of 1E17 cm⁻³ to 1E19 cm⁻³. The well region may be provided in various manners in the art, which will not be described in detail here.

On the substrate 1001, a first source/drain defining layer 1003, a first auxiliary layer 1005, a first channel defining layer 1007, a third auxiliary layer 1009, a body contact defining layer 1011, a fourth auxiliary layer 1013, a second channel defining layer 1015, a second auxiliary layer 1017 and a second source/drain defining layer 1019 may be formed sequentially by, for example, an epitaxial growth. The layers grown on the substrate 1001 may be single-crystal semiconductor layers and may have crystal interfaces therebetween.

The first source/drain defining layer 1003 and the second source/drain defining layer 1019 may subsequently define a position of a source/drain region, and may respectively have a thickness, for example, in a range of 20 nm to 200 nm. The first source/drain defining layer 1003 and the second source/drain defining layer 1019 may be doped with a dopant having a particular conduction type (e.g., an n-type conduction for an n-type device, or a p-type conduction for a p-type device) and a particular concentration in a range of 1E19 cm⁻³ to 1E20 cm⁻³, for example, by in-situ doping during growth.

The body contact defining layer 1011 may subsequently define a position of a body contact, and may have a thickness of, for example, about 10 nm. In order to optimize the device performance such as adjusting a threshold voltage (Vt), the body contact defining layer 1011 may be doped with a dopant having a particular conduction type (e.g., a p-type conduction for an n-type device, or an n-type conduction for a p-type device) and a particular concentration in a range of 1E19 cm⁻³ to 1E20 cm⁻³, for example, by in-situ doping during growth.

The first channel defining layer 1007, the third auxiliary layer 1009, the fourth auxiliary layer 1013 and the second channel defining layer 1015 together with the body contact defining layer 1011 may subsequently define a position of a channel region. Each of the third auxiliary layer 1009 and the fourth auxiliary layer 1013 may have a thickness of, for example, about 10 nm. In order to optimize the device performance such as adjusting the Vt, at least one of the third auxiliary layer 1009 or the fourth auxiliary layer 1013 may be doped, for example, by in-situ doping during growth, with a doping concentration in a range of 1E19 cm⁻³ to 1E20 cm⁻³.

Since the layers are doped separately, a doping concentration gradient may be formed therebetween.

The first source/drain defining layer 1003, the first auxiliary layer 1005, the first channel defining layer 1007, the third auxiliary layer 1009, the body contact defining layer 1011, the fourth auxiliary layer 1013, the second channel defining layer 1015, the second auxiliary layer 1017 and the second source/drain defining layer 1019 may contain various suitable semiconductor materials, e.g., an elemental semiconductor material such as Si or Ge, or a compound semiconductor material such as SiGe, etc. In order to provide appropriate etching selectivity in subsequent processes, adjacent layers in these layers may have etching selectivity between each other. For example, if the substrate 1001 is a Si wafer, the first source/drain defining layer 1003, the first auxiliary layer 1005, the body contact defining layer 1011, the second auxiliary layer 1017 and the second source/drain defining layer 1019 may contain Si, while the first channel defining layer 1007, the third auxiliary layer 1009, the fourth auxiliary layer 1013 and the second channel defining layer 1015 may contain SiGe (for example, in which an atomic percentage of Ge is in a range of 10% to 30%).

For the convenience of patterning, as shown in FIG. 2, an etching stop layer 1021, a mandrel layer 1023 and a hard mask layer 1025 may be sequentially formed on the stack of the above-mentioned semiconductor layers, for example, by deposition. For example, the etching stop layer 1021 may contain an oxide (e.g., silicon oxide), the mandrel layer 1023 may contain amorphous silicon or polysilicon, and the hard mask layer 1025 may contain an oxide (e.g., silicon oxide).

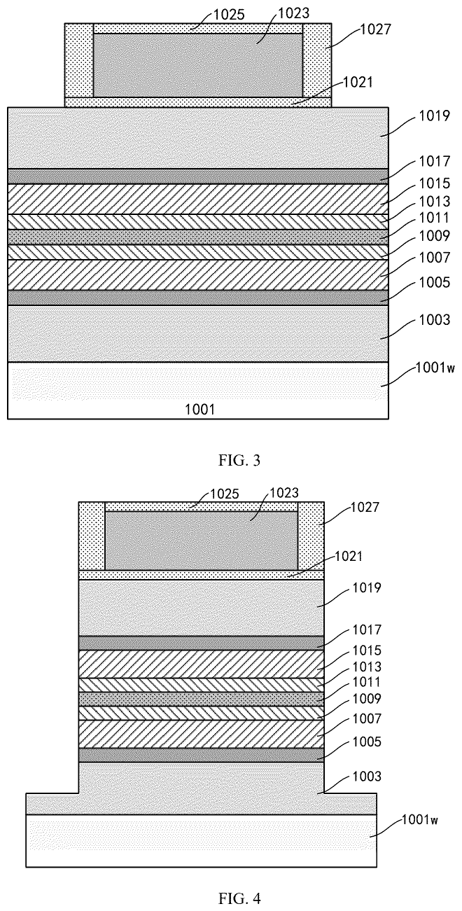

As shown in FIG. 3, a photoresist (not shown) may be formed on the hard mask layer 1025 and patterned by photolithography to have a vertical sidewall extending in a first direction (a direction perpendicular to a paper surface in FIG. 3). Using the patterned photoresist as an etching mask, the hard mask layer 1025 and the mandrel layer 1023 may be selectively etched sequentially by, for example, reactive ion etching (RIE), so that the pattern of the photoresist is transferred to the hard mask layer 1025 and the mandrel layer 1023. The RIE may be performed in a vertical direction. The etching may stop at the etching stop layer 1021. After that, the photoresist may be removed. Accordingly, the mandrel layer 1023 (and the hard mask layer 1025) may have a vertical sidewall extending in the first direction.

A spacer 1027 may be formed on such sidewall. For example, a certain thickness of oxide may be deposited in a substantially conformal manner, and then an anisotropic etching such as RIE (which may stop at the etching stop layer 1021) may be performed on the deposited oxide layer in the vertical direction, so as to remove a laterally extending portion and leave a vertically extending portion, thereby obtaining the spacer 1027. The spacer 1027 may subsequently be used to at least partially define a horizontal size of the second source/drain layer.

Interfaces between the spacer 1027, the hard mask layer 1025 and the etching stop layer 1021 are shown in the figures in order to clearly illustrate positions of the three (to facilitate understanding of readers). It should be noted that the spacer 1027, the hard mask layer 1025 and the etching stop layer 1021 are all oxides in this example.

As shown in FIG. 4, using the spacer 1027 and the hard mask layer 1025 as an etching mask, the second source/drain defining layer 1019, the second auxiliary layer 1017, the second channel defining layer 1015, the fourth auxiliary layer 1013, the body contact defining layer 1011, the third auxiliary layer 1009, the first channel defining layer 1007, the first auxiliary layer 1005 and the first source/drain defining layer 1003 are selectively etched sequentially, for example, by RIE, so that the stack of semiconductor layers may have a vertical sidewall extending in the first direction as a growth surface of the channel layer. The RIE may be performed in the vertical direction, and may stop inside the first source/drain defining layer 1003 instead of reaching a bottom surface of the first source/drain defining layer 1003.

As shown in FIG. 5, a channel layer 1029 may be formed by an epitaxial growth. A selective epitaxial growth may be performed so that the channel layer 1029 may be formed only on a surface of the semiconductor material. The channel layer 1029 may extend substantially in the vertical direction and have a thickness in a range of 10 nm to 20 nm.

A silicon material is taken as an example here in describing the channel layer 1029. However, the present disclosure is not limited to this. The material of the channel layer 1029 may be appropriately selected according to performance requirements of the design for the device. For example, the channel layer 1029 may contain various semiconductor materials, e.g., an elemental semiconductor material such as Si, Ge, etc., or a compound semiconductor material such as SiGe, InP, GaAs, InGaAs, etc.

The dopant may be driven from the body contact defining layer 1011 into the channel layer 1029 by annealing, so that a doping concentration in a first portion (see region A1 in FIG. 5) of the channel layer 1029 connected to the body contact defining layer 1011 is higher than a doping concentration in a second portion (see regions A2 in FIG. 5) of the channel layer 1029 adjacent to the first portion.

In a process of driving the dopant in the body contact defining layer 1011 into the channel layer 1029, the dopant in the first source/drain defining layer 1003 may be driven vertically (more specifically, upward) into the first auxiliary layer 1005 (and may also be driven laterally into a portion of the channel layer 1029 on a sidewall of the first source/drain defining layer 1003 and a portion of the channel layer 1029 on a sidewall of the first auxiliary layer 1005), and the dopant in the second source/drain defining layer 1019 may be driven vertically (more specifically, downward) into the second auxiliary layer 1017 (and may also be driven laterally into a portion of the channel layer 1029 on a sidewall of the second source/drain defining layer 1019 and a portion of the channel layer 1029 on a sidewall of the second auxiliary layer 1017). By providing the first auxiliary layer 1005 and the second auxiliary layer 1017, the portion of the channel layer 1029 on the sidewall of the first auxiliary layer 1005 and the portion of the channel layer 1029 on the sidewall of the second auxiliary layer 1017 (see regions A3 in FIG. 5) may absorb the dopants from the first source/drain defining layer 1003 and the second source/drain defining layer 1019 to inhibit these dopants from entering into the portion of the channel layer 1029 adjacent to the first portion (see the region A1 in FIG. 5), so that a partial region (the second portion as mentioned above, see the regions A2 in FIG. 5) in the portion of the channel layer 1029 on the sidewall of the first channel defining layer 1007 and in the portion of the channel layer 1029 on the sidewall of the second channel defining layer 1015 may remain lightly doped relative to the first portion (see the region A1 in FIG. 5).

The first auxiliary layer 1005 and the second auxiliary layer 1017 may be thin layers of about 10 nm. After annealing, the first auxiliary layer 1005 and the second auxiliary layer 1017 contain dopants from the first source/drain defining layer 1003 and the second source/drain defining layer 1019 (and contain the same material as the first source/drain defining layer 1003 and the second source/drain defining layer 1019 in this example). Therefore, the first auxiliary layer 1005 together with the first source/drain defining layer 1003 may be regarded as the first source/drain defining layer 1003, and the second auxiliary layer 1017 together with the second source/drain defining layer 1019 may be regarded as the second source/drain defining layer 1019. Therefore, the first auxiliary layer 1005 and the second auxiliary layer 1017 will not be shown separately in the following figures.

The dopant in the third auxiliary layer 1009 may be driven vertically (more specifically, upward) into the first channel defining layer 1007 (and may also be driven laterally into a portion of the channel layer 1029 on a sidewall of the third auxiliary layer 1009 and a portion of the channel layer 1029 on a sidewall of the first channel defining layer 1007), and the dopant in the fourth auxiliary layer 1013 may be driven vertically (more specifically, downward) into the second channel defining layer 1015 (and may also be driven laterally into a portion of the channel layer 1029 on a sidewall of the fourth auxiliary layer 1013 and a portion of the channel layer 1029 on a sidewall of the second channel defining layer 1015). The dopant in the body contact defining layer 1011 may be driven into the portion of the channel layer 1029 on the sidewall of the body contact defining layer 1011. By providing the third auxiliary layer 1009 and the fourth auxiliary layer 1013, the channel layer 1029 may obtain the first portion (see the region A1 in FIG. 5) that is relatively wide in the vertical direction, so that a height of the first portion in the vertical direction is greater than a height of the body contact defining layer 1011. Accordingly, a partial region (the first portion as mentioned above, see the region A1 in FIG. 5) of the channel layer 1029 on the sidewall of the body contact defining layer 1011, on the sidewall of the third auxiliary layer 1009, on the sidewall of the fourth auxiliary layer 1013, on an upper part of the sidewall of the first channel defining layer 1007 and on a lower part of the sidewall of the second channel defining layer 1015 may remain highly doped relative to the second portion (see the regions A2 in FIG. 5).

The process of driving the dopants in the first source/drain defining layer 1003, the third auxiliary layer 1009, the body contact defining layer 1011, the fourth auxiliary layer 1013 and the second source/drain defining layer 1019 into the channel layer 1029 is substantially a process of diffusion of the dopants in the first source/drain defining layer 1003, the third auxiliary layer 1009, the body contact defining layer 1011, the fourth auxiliary layer 1013 and the second source/drain defining layer 1019 to the channel layer 1029. In this example, the stack structure is symmetrical with respect to the body contact defining layer 1011. Accordingly, a diffusion degree of the dopant in the first source/drain defining layer 1003 to the channel layer 1029 is substantially the same as a diffusion degree of the dopant in the second source/drain defining layer 1019 to the channel layer 1029, that is, a concentration distribution of the dopant in the channel layer 1029 into which the dopant has been driven is also symmetrical with respect to the body contact defining layer 1011, so that the highly-doped first portion of the channel layer 1029 is substantially symmetrical with respect to the body contact. As another example, the stack structure may also be asymmetrical with respect to the body contact defining layer 1011. Accordingly, a diffusion degree of the dopant in the first source/drain defining layer 1003 to the channel layer 1029 is different from a diffusion degree of the dopant in the second source/drain defining layer 1019 to the channel layer 1029, that is, a concentration distribution of the dopant in the channel layer 1029 into which the dopant has been driven is asymmetrical with respect to the body contact defining layer 1011, so that the highly-doped first portion of the channel layer 1029 is asymmetrical with respect to the body contact.

In FIG. 5, the region A1, the regions A2 and the regions A3 are shaded for ease of understanding. For convenience and clarity, these doping regions will not be shown separately in the following figures.

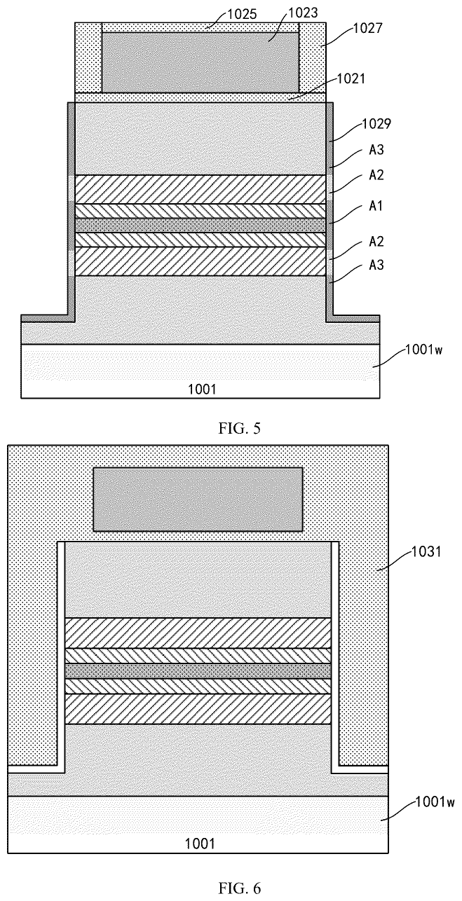

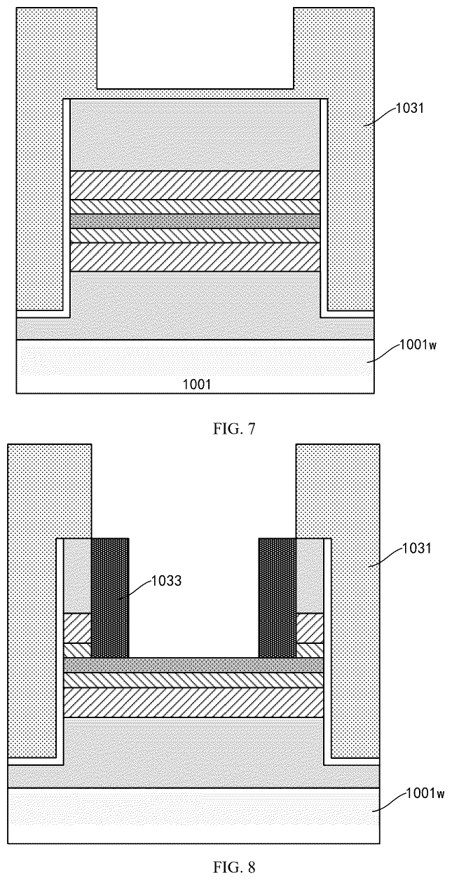

As shown in FIG. 6, a first dielectric layer 1031 may be formed by, for example, deposition, on the first source/drain defining layer 1003. For example, the first dielectric layer 1031 may contain an oxide. For convenience, the etching stop layer 1021, the spacer 1027 and the upper hard mask layer 1025, which are also oxides, are shown as a whole in the figure. Then, as shown in FIG. 7, a planarization such as chemical mechanical polishing (CMP) may be performed on the deposited first dielectric layer 1031, and the CMP may stop at the mandrel layer 1023. The mandrel layer 1023 may be removed by selective etching, such as wet etching using TMAH solution (stopping at the etching stop layer 1021). As a result, an opening (corresponding to a region surrounded by the closed ring-shaped spacer 1027) is formed in the first dielectric layer 1031.

As shown in FIG. 8, using the spacer 1027 as an etching mask, the etching stop layer 1021, the second source/drain defining layer 1019, the second channel defining layer 1015 and the fourth auxiliary layer 1013 may be selectively etched sequentially via the opening by, for example, RIE in the vertical direction, so as to expose the body contact defining layer 1011 and form a spacer 1033 on the body contact defining layer 1011.

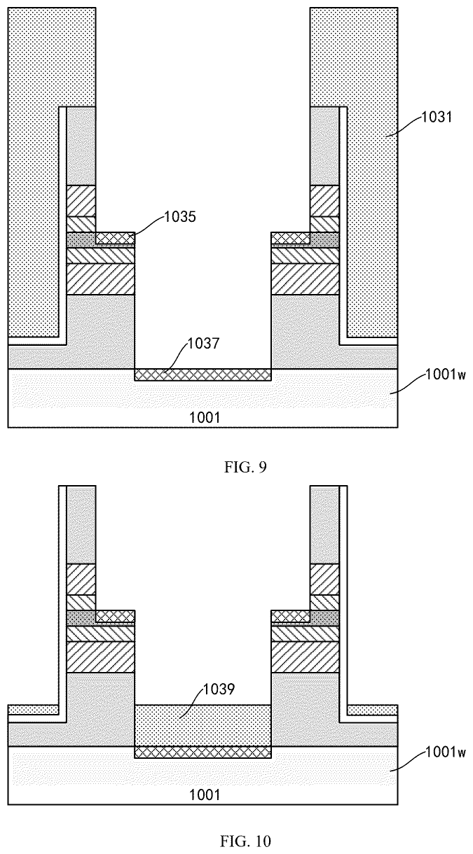

Then, as shown in FIG. 9, using the spacer 1033 (as well as the spacer 1027 and the first dielectric layer 1031) as an etching mask, the body contact defining layer 1011, the third auxiliary layer 1009, the first channel defining layer 1007 and the first source/drain defining layer 1003 may be selectively etched sequentially by, for example, RIE in the vertical direction, so as to expose the well region 1001w. Alternatively, photolithography and direct etching methods may be used instead of the spacer process shown in FIG. 8 to expose the well region 1001w. In this example, since both the first source/drain defining layer 1003 and the substrate 1001 contain Si, the etching of the first source/drain defining layer 1003 may proceed into the well region 1001w. Then, the spacer 1033 may be removed by selective etching.

In addition, in order to reduce a contact resistance, a vertical ion implantation and an annealing may be performed to form relatively highly doped contact regions (see 1035 and 1037 in FIG. 9, which have the same conduction type as the body contact defining layer 1011 and the well region 1001w) in the body contact defining layer 1011 and the well region 1001w, respectively. It is also possible to form only the contact region 1035.

An oxide may be deposited on the well region 1001w and planarized by CMP to form a second dielectric layer 1039 (together with the previous first dielectric layer 1031). As shown in FIG. 10, the second dielectric layer 1039 may be etched to a depth by, for example, wet etching. A surface of the second dielectric layer 1039 after etching may be lower than a top surface of the first source/drain defining layer 1003, so that a gate stack subsequently formed on the surface of the second dielectric layer 1039 may intersect with an entire height of the channel layer.

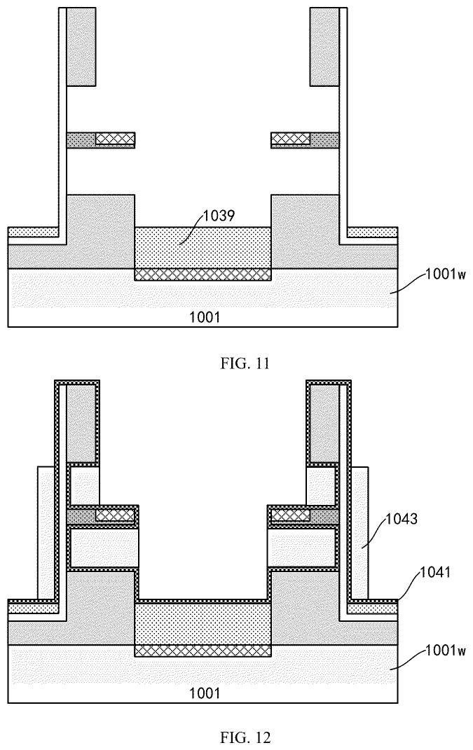

As shown in FIG. 11, the second channel defining layer 1015, the fourth auxiliary layer 1013, the third auxiliary layer 1009 and the first channel defining layer 1007 are removed by selective dry or wet etching, so that a body contact is formed in the body contact defining layer 1011.

In this way, a definition of an active region, especially the source/drain region and the channel portion therein, is completed. A gate stack may be formed on such defined active region to complete the device manufacturing.

The gate stack may be formed on the first dielectric layer 1031 and the second dielectric layer 1039. The gate stack may include a gate dielectric layer 1041 and a gate conductor layer 1043. For example, the gate dielectric layer 1041 may include a high-k dielectric (e.g., HfO₂) layer with a thickness in a range of 1 nm to 10 nm, which is formed by, for example, deposition. The gate dielectric layer 1041 may be formed in a substantially conformal manner. Before the formation of the gate dielectric layer 1041, a thin interface layer, such as an oxide of about 0.3 nm to 2 nm, may be formed by, for example, oxidation or deposition. The gate conductor layer 1043 may include a work function layer such as TiN, TiAlN, a material containing Zr, Ru or La, etc., and may further include a conductive material layer such as W as needed. The gate conductor layer 1043 may be etched back, so that a top surface of the gate conductor layer 1043 may be higher than a bottom surface of the second source/drain defining layer 1019 to ensure overlap with the channel region. In practice, the gate conductor layer 1043 in each separated portion may include different conductive material layers to achieve different work functions according to actual needs.

A photoresist may be formed on the gate conductor layer 1043 and patterned to surround an outer periphery of the channel region in a plan view. Using such patterned photoresist and the spacer 1027 mentioned above as an etching mask, the gate conductor layer 1043 may be etched by selective etching, such as RIE in the vertical direction. The etching of the gate conductor layer 1043 may stop at the gate dielectric layer 1041. Accordingly, the gate conductor layer 1043 may be formed into a shape surrounding the channel layer 1029, and thus a vertical nanochannel transistor may be obtained. After that, the photoresist may be removed as shown in FIG. 12.

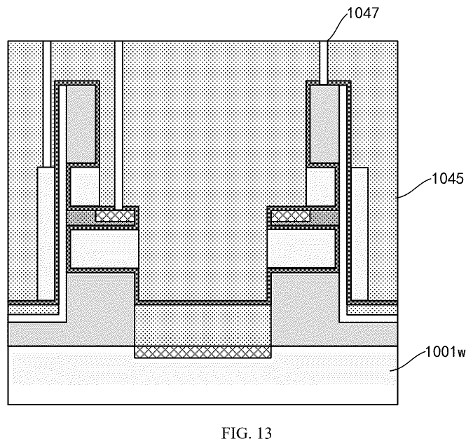

As shown in FIG. 13, a third dielectric layer 1045 may be formed on the substrate by, for example, deposition followed by planarization. A contact hole may then be formed, and the contact hole may be filled with a conductive material such as metal to form a contact portion 1047. The contact portion 1047 may include a contact portion penetrating the third dielectric layer 1045 to connect to the second source/drain defining layer 1019, a contact portion penetrating the third dielectric layer 1045 to connect to the body contact defining layer 1011, and a contact portion penetrating the third dielectric layer 1045 to connect to the gate stack (specifically, the gate conductor layer 1043). The contact portion 1047 may further include a contact portion penetrating the third dielectric layer 1045 to connect to the first source/drain defining layer 1003, and a contact portion penetrating the third dielectric layer 1045 to connect to the well region 1001w (not shown). It may be understood that in addition to the methods of forming the contact portions of the semiconductor device provided in the present disclosure, various other methods in the art may also be used to form the contact portions of the semiconductor device, which will not be described in detail here.

After that, the subsequent processes may be performed, which will not be described in detail here.

The semiconductor device according to the embodiments of the present disclosure may be applied to various electronic apparatuses. Accordingly, the present disclosure further provides an electronic apparatus including the semiconductor device described above. The electronic apparatus may further include a display screen, a wireless transceiver, or other components. Such electronic apparatus may be, for example, a smart phone, a personal computer (PC), a tablet computer, a wearable intelligence apparatus, an artificial intelligence apparatus, a mobile power supply, etc.

According to the embodiments of the present disclosure, a method of manufacturing a system-on-a-chip (SoC) is further provided. The method may include the methods mentioned above. Specifically, a variety of devices may be integrated on a chip, and at least some of the devices are manufactured according to the methods disclosed in the present disclosure.

In the above descriptions, the technical details such as patterning and etching of each layer have not been described in detail. However, those skilled in the art should understand that various technical means may be used to form layers, regions, etc. of desired shapes. In addition, in order to form the same structure, those skilled in the art may also design a method that is not completely the same as the method described above. In addition, although various embodiments are described above separately, this does not mean that the measures in the various embodiments may not be advantageously used in combination.

The embodiments of the present disclosure have been described above. However, these embodiments are just for illustrative purposes, and are not intended to limit the scope of the present disclosure. The scope of the present disclosure is defined by the appended claims and their equivalents. Those skilled in the art may make various substitutions and modifications without departing from the scope of the present disclosure, and these substitutions and modifications should all fall within the scope of the present disclosure.

What is claimed is:

1. A semiconductor device, comprising:
a first source/drain layer, a channel layer and a second source/drain layer sequentially provided in a vertical direction on a substrate, wherein the channel layer is connected between the first source/drain layer and the second source/drain layer, and the channel layer has a doping profile along the vertical direction, in which a middle portion of the channel layer has a high doping concentration and end portions of the channel layer have a low doping concentration; and
a body contact connected to the middle portion of the channel layer,
wherein the middle portion of the channel layer has a height in the vertical direction greater than a height of the body contact in the vertical direction.

2. The semiconductor device according to claim 1, wherein the middle portion of the channel layer has a substantially uniform doping profile.

3. The semiconductor device according to claim 1, wherein the middle portion of the channel layer is substantially symmetrical with respect to the body contact; or
wherein the middle portion of the channel layer is asymmetrical with respect to the body contact.

4. The semiconductor device according to claim 1, wherein an extension height of the middle portion of the channel layer relative to a top surface of the body contact in the vertical direction is substantially equal to an extension height of the middle portion of the channel layer relative to a bottom surface of the body contact in the vertical direction; or
wherein an extension height of the middle portion of the channel layer relative to a top surface of the body contact in the vertical direction is greater than an extension height of the middle portion of the channel layer relative to a bottom surface of the body contact in the vertical direction; or
wherein an extension height of the middle portion of the channel layer relative to a top surface of the body contact in the vertical direction is less than an extension height of the middle portion of the channel layer relative to a bottom surface of the body contact in the vertical direction.

5. The semiconductor device according to claim 1, wherein a doping type in the channel layer is opposite to a doping type in the first source/drain layer and in the second source/drain layer.

6. The semiconductor device according to claim 1, wherein the channel layer extends vertically.

7. The semiconductor device according to claim 1, wherein the body contact extends laterally.

8. A method of manufacturing a semiconductor device, comprising:
providing a stack of a first source/drain defining layer, a first channel defining layer, a body contact defining layer, a second channel defining layer and a second source/drain defining layer on a substrate, wherein the body contact defining layer contains a dopant;
forming a channel layer on a vertical sidewall of the stack; and
driving the dopant in the body contact defining layer into the channel layer to form a doping profile in the channel layer, so that a doping concentration in a first portion of the channel layer connected to the body contact defining layer is greater than a doping concentration in a second portion of the channel layer adjacent to the first portion.

9. The method according to claim 8, further comprising:
forming a first auxiliary layer between the first source/drain defining layer and the first channel defining layer; and
forming a second auxiliary layer between the second channel defining layer and the second source/drain defining layer,
wherein, in a process of driving the dopant in the body contact defining layer into the channel layer, a dopant in the first source/drain defining layer is driven into a portion of the channel layer on a sidewall of the first auxiliary layer, and a dopant in the second source/drain defining layer is driven into a portion of the channel layer on a sidewall of the second auxiliary layer, so that a partial region in a portion of the channel layer on a sidewall of the first channel defining layer and in a portion of the channel layer on a sidewall of the second channel defining layer remains lightly doped relative to the first portion.

10. The method according to claim 9, further comprising:
forming a third auxiliary layer between the first channel defining layer and the body contact defining layer; and
forming a fourth auxiliary layer between the body contact defining layer and the second channel defining layer;
wherein, in the process of driving the dopant in the body contact defining layer into the channel layer, a dopant in the third auxiliary layer is driven into the portion of the channel layer on the sidewall of the first channel defining layer, a dopant in the fourth auxiliary layer is driven into the portion of the channel layer on the sidewall of the second channel defining layer, and the dopant in the body contact defining layer is driven into a portion of the channel layer on a sidewall of the body contact defining layer, so that a partial region of the channel layer on the sidewall of the body contact defining layer, on a sidewall of the third auxiliary layer, on a sidewall of the fourth auxiliary layer, on an upper part of the sidewall of the first channel defining layer and on a lower part of the sidewall of the second channel defining layer remains highly doped relative to the second portion.
